(19) United States
(12) Patent Application Publication
(10) Pub. No.: US 2026/0114226 A1
(43) Pub. Date: Apr. 23, 2026

(54) EQUIPMENT FOR HANDLING SEMICONDUCTOR CARRIERS

(71) Applicant: CAPT Semiconductor (Shanghai) Co., Ltd., Shanghai (CN)

(72) Inventor: Chun-hua Li, Shanghai (CN)

(21) Appl. No.: 19/353,630

(22) Filed: Oct. 9, 2025

(30) Foreign Application Priority Data
Oct. 21, 2024 (CN) 2024114739135

(51) Int. Cl. H01L 21/677; B25J 11/00; H01L 21/67; H01L 21/687

(52) U.S. Cl. CPC H10P 72/3311; B25J 11/0095; H10P 72/0434; H10P 72/7602

(57) ABSTRACT

The Embodiments of the present invention relate to an equipment for handling semiconductor carriers, comprising: a processing chamber, n heating chambers, at least n+1 stockers, a lifter, and a robot. The n heating chambers are communicated with the processing chamber. The at least n+1 stockers are disposed within the processing chamber. The lifter is disposed within the processing chamber and configured to transfer a high-temperature-resistant, transferable metal cassette to one of the n heating chambers or the at least n+1 stockers, the transferable metal cassette being configured to accommodate and batch-transfer a plurality of semiconductor carriers; the at least n heating chambers and the at least n+1 stockers being configured to accommodate the transferable metal cassette. The robot is disposed within the processing chamber and configured to sequentially transfer the plurality of semiconductor carriers to the transferable metal cassette via a carrier loading system.

### CROSS REFERENCE TO RELATED APPLICATIONS

The present application claims the benefit of Chinese Patent Application No. 2024114739135 filed on Oct. 21, 2024, the contents of which are incorporated herein by reference in their entirety.

### FIELD OF TECHNOLOGY

The present invention relates to an equipment for handling semiconductor carriers, particularly an equipment for handling semiconductor carriers that can reduce the instances where heating chambers remain idle while waiting for transfer of semiconductor carriers and that effectively reduce the production floor area of a semiconductor manufacturing plant.

### BACKGROUND

Semiconductor carriers require efficient transfer and positioning between different processing equipment on the production line. To meet this requirement, the currently widely used equipment front-end module (EFEM) covers most types of semiconductor processing/inspection equipment, including but not limited to etching, CMP, PVD/CVD/ALD, inspection/measurement, thermal curing, annealing, polishing, ion implantation, resist removal, cleaning, and photolithography. By integrating automated material handling system (AMHS) with the equipment front-end modules for different processing equipment, semiconductor carriers can be transferred accurately and contamination-free, and a large number of semiconductor manufacturing processes can be performed in an environment with high precision, high efficiency, high cleanliness, and high reliability.

### SUMMARY

An embodiment of the present invention relates to an equipment for handling semiconductor carriers, comprising: a processing chamber, n heating chambers, at least n+1 stockers, a lifter, and a robot. The n heating chambers are communicated with the processing chamber. The at least n+1 stockers are disposed within the processing chamber. The lifter is disposed within the processing chamber and configured to transfer a high-temperature-resistant, transferable metal cassette to one of the n heating chambers or the at least n+1 stockers, the transferable metal cassette being configured to accommodate and batch-transfer a plurality of semiconductor carriers; the at least n heating chambers and the at least n+1 stockers being configured to accommodate the transferable metal cassette. The robot is disposed within the processing chamber and configured to sequentially transfer the plurality of semiconductor carriers to the transferable metal cassette via a carrier loading system. Wherein n is an integer greater than or equal to 1.

Another embodiment of the present invention relates to an equipment for handling semiconductor carriers, comprising: a processor configured to cause: a robot positioned in a processing chamber to perform a first sequential transfer: a plurality of semiconductor carriers are sequentially transferred from a carrier loading system to a first transferable metal cassette; and the transferable metal cassette positioned in the processing chamber to be transferred to a stocker or a heating chamber.

### BRIEF DESCRIPTION OF THE DRAWINGS

The various aspects of the present invention are best understood when reading the following detailed description and accompanying drawings. It should be noted that, in accordance with standard practice in the art, the various features in the drawings are not drawn to scale. In fact, the dimensions of some features may be intentionally exaggerated or reduced for clarity of description.

FIG. 1A illustrates a top view schematically illustrating the components of an equipment for handling semiconductor carriers according to some embodiments of the present invention.

FIG. 1B illustrates a front view schematically illustrating a heating chamber for handling semiconductor carriers according to some embodiments of the present invention.

FIG. 1C illustrates a front view schematically illustrating a stocker for handling semiconductor carriers according to some embodiments of the present invention.

FIG. 2 illustrates a flow chart of the steps for performing a multi-batch heating treatment on semiconductor carriers according to some embodiments of the present invention.

FIG. 3 illustrates a schematic diagram of the duration of different steps in the multi-batch heating treatment process according to some embodiments of the present invention.

FIG. 4A illustrates a top view schematically illustrating the components of an equipment for handling semiconductor carriers according to some embodiments of the present invention.

FIG. 4B illustrates a front view schematically illustrating a heating chamber for handling semiconductor carriers according to some embodiments of the present invention.

FIG. 4C illustrates a front view schematically illustrating a stocker for handling semiconductor carriers according to some embodiments of the present invention.

FIG. 5 illustrates a flow chart of the steps involved in performing a multi-batch heating treatment on semiconductor carriers according to some embodiments of the present invention.

FIG. 6 illustrates a schematic diagram of the duration of different steps in the multi-batch heating treatment process according to some embodiments of the present invention.

FIG. 7 illustrates a schematic diagram of the duration of different steps in the multi-batch heating treatment process according to some embodiments of the present invention.

### DESCRIPTION OF THE EMBODIMENTS

The following disclosure provides many different embodiments or examples of different components for implementing the provided subject matter. Specific examples of components and arrangements are described below to simplify this disclosure. Surely, this is merely an example and is not intended to be restrictive. For example, in the following description, a first component formed above or on a second component may include an embodiment in which the first and second components are formed to be in direct contact, and may also include an embodiment in which an additional component may be formed between the first and second components so that the first and second components may not be in direct contact. In addition, this disclosure may repeat reference numbers and/or letters in various examples. This repetition is for simplicity and clarity purposes and does not itself indicate the relationship between the various embodiments and/or configurations discussed.

Furthermore, for ease of description, spatially relative terms such as “under”, “beneath”, “below”, “on”, “over”, “above” and the like may be used herein to describe one component or member's relationship to another component or member illustrated in the figures. Spatially relative terms are intended to encompass different orientations of the device in use or operation in addition to the orientation depicted in the figures. The device may be otherwise oriented (rotated 90 degrees or at other orientations) and the spatially relative descriptors used herein should be interpreted similarly.

As used herein, terms such as “first,” “second,” and “third” describe various components, elements, regions, layers, and/or sections, but such components, elements, regions, layers, and/or sections should not be limited by such terms. Such terms are only used to distinguish one component, element, region, layer, or section from another. Terms such as “first,” “second,” and “third” when used herein do not imply a sequence or order unless clearly indicated by the context.

The present invention relates to an equipment for handling semiconductor carriers. Its function includes performing heat treatment on semiconductor carriers, such as semiconductor wafers. This heat treatment is intended to cure materials applied to the semiconductor carriers—such as polyimide (PI), benzocyclobutene (BCB), underfill epoxy resin, and the like—by heating and baking these materials to solidify them. In some practical applications, this equipment may be referred to as a clean oven or bake oven, capable of delivering a clean, dust-free, high-temperature environment suitable for thermal processing.

If the semiconductor manufacturing process involves the use of a heat-curing processes to simultaneously heat multiple semiconductor carriers, then the processing workflow will inevitably require the individual transfer of each multiple semiconductor carriers, including steps such as picking up, moving, and placing the multiple semiconductor carriers. During the semiconductor manufacturing process, it is necessary to transfer these multiple semiconductor carriers—delivered from other stations (such as other semiconductor processing equipment)—into the oven for heating, and then remove the heated multiple heated semiconductor carriers from the oven and reload them onto the transportation route so that these heated semiconductor carriers can be sent to other stations for subsequent processing.

In some comparative embodiments, while semiconductor carriers are transferred one-by-one, the oven's heating chamber is in an idle state, meaning that it is not performing any heating operation. Specifically, besides the periods when semiconductor carriers are sequentially placed into the oven and removed from the oven, during which the oven is necessarily idle due to loading/unloading operations, there are other instances—such as when the semiconductor carriers are being unloaded from the automated material handling system (AMHS) to the oven's station, and during loading the semiconductor carriers back onto the AMHS—when the heating chamber is also idle. These idle states, which are not caused by the oven's own operating procedures, significantly reduce the efficiency of the semiconductor manufacturing process.

One of the purposes of the present invention is to improve the idle states that are not caused by the oven's own operating process, so as to keep the oven in a non-idle state as much as possible. This increases the number of semiconductor carriers that can be heated per unit time, thereby improving the efficiency of the semiconductor manufacturing process.

The equipment for handling semiconductor carriers of the present invention may serve as one of the stations in the semiconductor manufacturing process. During a semiconductor manufacturing process, semi-finished devices such as semiconductor carriers or work-in-process (WIP) components are transported or transferred among different stations. In some embodiments, the semiconductor carriers may be moved between stations using a transport vehicle in an automated material handling system, such as an automatic guided vehicle (AGV), a personal guided vehicle (PGV), a rail guided vehicle (RGV), an overhead shuttle (OHS), or an overhead hoist transport (OHT). During transportation, in order to maintain production quality, sealing measures can be used to prevent external contaminants from contacting the semiconductor carriers being transported, ensuring that the semiconductor carriers remain clean, and/or protecting the semiconductor carriers from falling off the transport vehicle.

In some embodiments, the semiconductor carriers handled by the present invention may include semiconductor wafers, semiconductor substrates, glass substrates, panels, etc.

In some embodiments, taking semiconductor wafers as an example of semiconductor carriers, the sealing measure is to place multiple semiconductor wafers to be heated into a front opening unified pod (FOUP), which is then transported to the equipment for handling semiconductor carriers of the present invention by way of an overhead hoist transport.

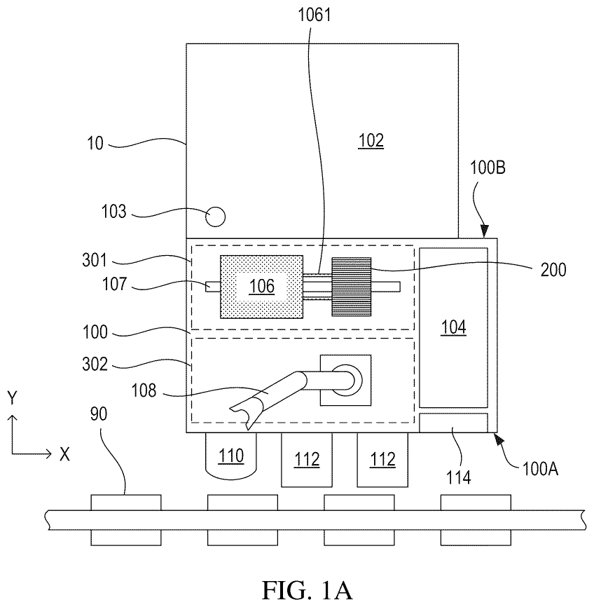

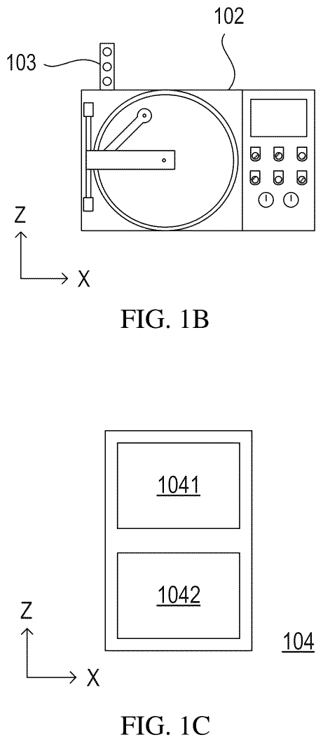

Referring to FIG. 1A, which is a schematic diagram illustrating the structural components of some embodiments of the present invention. In some embodiments, an equipment 10 for handling semiconductor carriers includes a processing chamber 100, n heating chambers 102, at least n+1 stockers 104, a lifter 106, and a robot 108, where n is an integer greater than or equal to 1.

The processing chamber 100 can be an automated semiconductor carrier loading and unloading apparatus based on an equipment front-end module (EFEM) architecture. In some embodiments, the processing chamber 100 may consist of an interior of a frame forming a substantially enclosed semiconductor carrier loading and unloading chamber, which, form a top view (e.g., as shown in FIG. 1A), has a first side 100A and a second side 100B opposite the first side 100A. In some embodiments, the processing chamber 100 uses the first side 100A as one or more load ports 112 that serve as the interface for loading and unloading operations with the FOUP 90. The load ports 112 serve as a carrier loading system for transferring semiconductor carriers from the FOUP 90 into the processing chamber 100.

Referring to FIGS. 1A and 1B, where FIG. 1B is a front view of the heating chamber according to some embodiments of the present invention. The n heating chambers 102 communicate with the processing chamber 100, and each heating chamber 102 may possess the structure of an oven, so the n heating chambers 102 may comprise a set of n ovens. These heating chambers 102 are used to perform heat treatment at a specific temperature or within a temperature range for the semiconductor carriers, and provide a specific type and concentration of gaseous atmosphere during heating as needed. In some embodiments, the heating chamber 102 is disposed on the second side 100B near the processing chamber 100. In some embodiments, the top of the heating chamber 102 may be equipped with a working light 103, which is configured to visually indicate the operating status of the heating chamber 102 (e.g., in an idle process/operating process) using optical signals (e.g., a tri-color alerts), facilitating observation and monitoring.

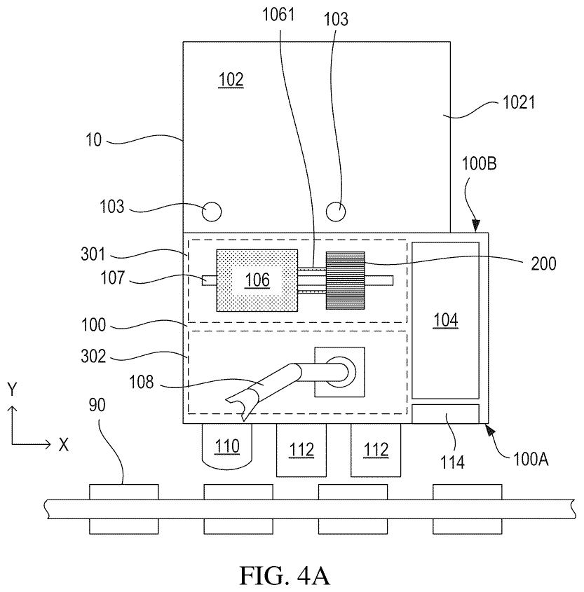

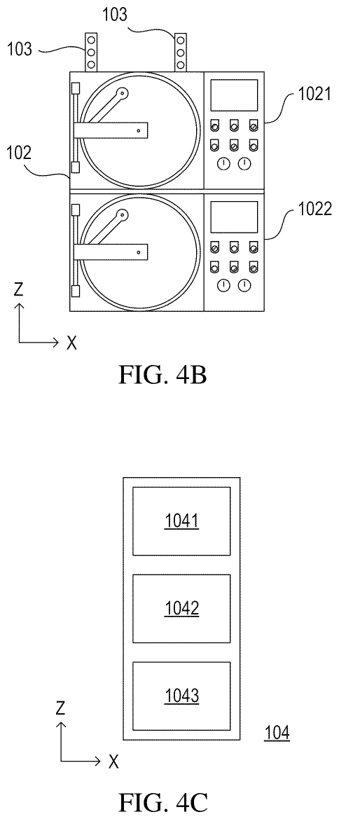

In some embodiments, n heating chambers 102 are vertically stacked on the second side 100B of a processing chamber 100 to more efficiently utilize the floor space of a semiconductor fabrication plant (FAB). These embodiments are detailed in FIG. 4A and FIG. 4B. In some embodiments, the actual footprint of the equipment 10 for handling semiconductor carriers is approximately 7.8 square meters (2.05 meters*3.8 meters), whereas some comparative embodiments occupy approximately 12.2 square meters (3.4 meters*3.6 meters). One way the present invention reduces the footprint is to use vertically stacked heating chambers 102 to avoid the issue in some comparative embodiments where increasing the number of heating chambers to boost processing capacity of heated semiconductor carriers results in excessively large equipment footprint.

Referring to FIG. 1A and FIG. 1C, wherein FIG. 1C is a front view of a stocker according to some embodiments of the present invention. At least n+1 stockers 104 are disposed within a processing chamber 100 and serve as temporary storage spaces for placing operation objects (e.g., a transferable metal cassette 200, referred to as a metal cassette 200, which is used to accommodate and batch transfer a plurality of semiconductor carriers) during the transfer process. A lifter 106 is also disposed within the processing chamber 100 and is configured to transfer the metal cassette 200 to one of the n heating chambers 102 or one of the n+1 stockers 104.

In some embodiments of the present invention, the n heating chambers 102 and the at least n+1 stockers 104 are configured to accommodate the metal cassette 200; in other words, the number of stockers 104 in the present invention is greater than the number of heating chambers 102, for example, the stockers 104 outnumber the heating chambers 102 by at least one. In this way, it is ensured that throughout the transfer and operational workflow, including movement of the metal cassette 200 between the stocker 104 in the processing chamber 100 and the heating chamber 102 located at the second side 100B of the processing chamber 100, and when the metal cassette 200 receives the semiconductor carrier from the carrier loading system, the operation process will not be stalled due to lack of available space for a cassette. It specifically avoids scenarios where workflow must wait for another metal cassette 200 to be moved out first before freeing space, preventing the heating chamber 102 from being idled as a result.

For example, in some embodiments of the present invention, a stocker 104 is used to accommodate one metal cassette 200. At any given moment in the operation of the equipment for handling semiconductor carriers, one stocker 104 may contain a metal cassette 200 actively receiving multiple semiconductor carriers from the carrier loading system, while another stocker 104 may be vacant because its metal cassette 200 has been transferred into the heating chamber 102 for heating treatment. After the heating treatment is completed, the metal cassette 200 located in the heating chamber 102 is moved out and placed into the previously vacant stocker 104. At this time, the metal cassette 200, now loaded with semiconductor carriers, can be moved into the heating chamber 102 for subsequent heating treatment. That is, by minimizing idle time of the heating chamber 102, the equipment for handling semiconductor carriers of the present invention achieves improved operational efficiency. If the number of the stocker 104 equals to or even falls below the number of the heating chamber 102—such as both being 1—then after the heating treatment is completed, there is not sufficient space within the processing chamber 100 to accommodate the metal cassette 200 moved out from the heating chamber 102, because the only stocker 104 is occupied by the metal cassette 200 that was just loaded with semiconductor carriers. From another perspective, if the sole stocker 104 is reserved for the metal cassette 200 that is undergoing heat treatment in the heating chamber 102 (more precisely, for heating the semiconductor carriers in the metal cassette 200), then there is no spare space to accommodate another metal cassette 200 to receive the semiconductor carriers in preparation for the next batch of heating treatments.

In some embodiments, the metal cassette 200 used in the equipment for handling semiconductor carriers is made of metal materials capable of withstanding high-temperatures and high-pressures, suitable for the operational environment required by the semiconductor manufacturing heating process, and is used to accommodate and batch-transfer multiple semiconductor carriers. For example, depending on its design dimensions and the specifications of the semiconductor carriers, one metal cassette 200 can hold 12, 25, or 50 semiconductor carriers at full capacity, and the present invention is not limited to these examples. Because the metal cassette 200 can be directly transferred into the heating chamber 102 by the lifter 106, the purpose for batch transfer and batch heating of semiconductor carriers can be achieved.

In some embodiments, each of the at least n heating chambers 102 and the metal cassette 200 can be matched via kinematic coupling pins (KC pins) and corresponding slot structures to secure each metal cassette 200 within its respective heating chamber 102. In other embodiments, a magnetic mechanism can be used to secure the metal cassette 200 within the heating chamber 102. In some examples, the magnetic mechanism may incorporate necessary thermal insulation design depending on its installation location.

In some embodiments, the at least n+1 stockers 104 may be composed of a continuous platform or a plurality of discrete platforms within the processing chamber 100. For example, the at least n+1 stockers 104 may be a rack-type multi-layer structure (e.g., the first stocker 1041 and the second stocker 1042 shown in FIG. 1C). This rack-type multi-layer structure is similar to the previously described vertically stacked design for heating chambers, which can properly and efficiently utilize the floor area of a FAB and prevent the equipment 10 for handling semiconductor carriers from occupying excessive space. In some embodiments, each stocker 104 has a designated rack position number and is equipped with a detection unit so that the operators of the equipment 10 for handling semiconductor carriers or the automated control system can identify the free or occupied status of each stocker 104 in real time to efficiently and appropriately transfer the metal cassettes 200. For example, by calculating with an automated control system and aiming to, minimize the idle time of the heating chamber 102, the total movement distance for the lifter 106 to transfer multiple metal cassettes 200 between heating chambers 102 and stockers 104 is reduced. Furthermore, in some examples, the detection unit can also identify each metal cassette 200, for example, by using an imaging recognition to detect the code engraved on the metal cassette 200, thereby arranging or confirming the heating progress of each batch of semiconductor carriers. To accommodate the metal cassettes 200, the size of each stocker 104 must be at least equal to the footprint of the metal cassette 200.

In other embodiments, a portion of the lifter 106 may also serve as a stocker, such as a fork 1061 or similar component used by the lifter 106 for gripping and holding the metal cassette 200, which may be considered to serve as an additional usable temporary storage space. Therefore, in these other embodiments, at least n+2 stockers 104 may be defined within the processing chamber 100. In this case, one stocker 104 is a non-rack-type, atypical temporary storage space inside the processing chamber 100. For example, the lifter 106 may grip or hold an empty metal cassette 200 for receiving semiconductor carriers from the carrier loading system. In another example, the metal cassette 200 held or gripped by the lifter 106, after receiving semiconductor carriers from the carrier loading system, can be directly sent into the heating chamber 102 without passing through the rack-type stocker 104 as previously described.

In some embodiments, the lifter 106 can be placed on a lifter track 107 within the processing chamber 100, enabling the lifter 106 itself to move in a single direction within the processing chamber 100. As stated above, the lifter 106 is used to transfer metal cassette 200. In some embodiments, the lifter 106 is configured to move metal cassettes 200 and can vertically transport (z-axis), horizontally transport (x-axis, y-axis), or, where required, rotate the metal cassette 200 along any of these axes (angle θ). With respect to spatial layout within the processing chamber 100, in some embodiments, the lifter 106 is placed between the array of at least n heating chambers 102 and the at least n+1 stockers 104, enabling reciprocal transfer of the metal cassettes 200 between one of the at least n heating chambers 102 and one of the at least n+1 stockers 104. In the example shown in FIG. 1B and FIG. 1C in which there is one heating chamber 102 and at least two stockers 104, the first stocker 1041 is vertically stacked above the second stocker 1042, and the lifter 106 is configured for vertical movement to transfer the metal cassette 200 between the heating chamber 102 and the vertically stacked stockers 104. In other words, because the multiple stockers 104 in some embodiments of the present invention are stacked vertically, different stockers 104 or any stocker 104 and the heating chamber 102 may be located at different horizontal positions. Therefore, the lifter 106 moves vertically (z-axis direction) to position the metal cassette 200 at the appropriate horizontal positions for subsequent process handling.

The robot 108 is positioned within the processing chamber 100 and is configured to sequentially transfer the plurality of semiconductor carriers from the carrier loading system to the metal cassette 200. In contrast to the lifter 106 which batch-transfers semiconductor carriers by moving the metal cassette 200, the robot 108 performs sequential transfers for each individual semiconductor carrier, making this stage more time-consuming during the transfer process of semiconductor carriers. Specifically, in some embodiments, the robot 108 retrieves semiconductor carriers from the FOUP 90 located at the load port 112 on the first side 100A of the processing chamber 100, and sequentially places the semiconductor carriers in one of the metal cassettes 200 located within one of the stockers 104 in the processing chamber 100 (e.g., either a rack-type stocker or a stocker established by the lifter 106 holding the metal cassette 200). In some embodiments, the base of the robot 108 is fixed within the processing chamber 100. Its arm segment (or in some cases, a dual-arm structure) may acquire semiconductor carriers from the FOUP 90 using vacuum suction or edge gripping. Utilizing one or more joints of the robot 108, the robot 108 can perform forward and backward (x-axis), rotational (θ-axis), and vertical (z-axis) movements to transfer the semiconductor carriers into the metal cassette 200. In other embodiments, the base or arm segment of the robot 108 can be provided with a lateral movement axis to extend or expand its horizontal operational range of motion.

As described above, based on the distinction between sequential transfer and batch transfer, in some embodiments, the equipment 10 for handling semiconductor carriers within the processing chamber 100 can be specifically divided into a batch transfer zone 301 and a sequential transfer zone 302. The batch transfer zone 301 is situated adjacent to the at least n heating chambers 102. The sequential transfer zone 302 is located near the carrier loading system, and only sequential transfer operations are performed in the sequential transfer zone 302. In some embodiments, the robot 108 is located within the sequential transfer zone 302, while the lifter 106 and the lifter track 107 are located in a batch transfer zone 301.

In some embodiments, the equipment 10 for handling semiconductor carriers may further include an aligner 110. The aligner 110 is connected to the first side 100A of the processing chamber 100. The aligner 110 is a positioning and calibration device. In some cases, the aligner 110 performs pre-alignment of semiconductor carriers. For example, when the semiconductor carrier is a silicon wafer, a robot 108 cooperating with the aligner 110 places the silicon wafer on the aligner 110. The aligner 110 detects the eccentricity of the silicon wafer and/or the position of the notch of the silicon wafer, aligns the notch to a set angle, and then notifies the robot 108 to remove the silicon wafer. This ensures that each semiconductor carriers, such as a silicon wafer, can be placed in the metal cassette 200 in a uniform position.

In some embodiments, the equipment 10 for handling semiconductor carriers may further include a fan filter unit (FFU) to ensure the cleanliness level inside the processing chamber 100.

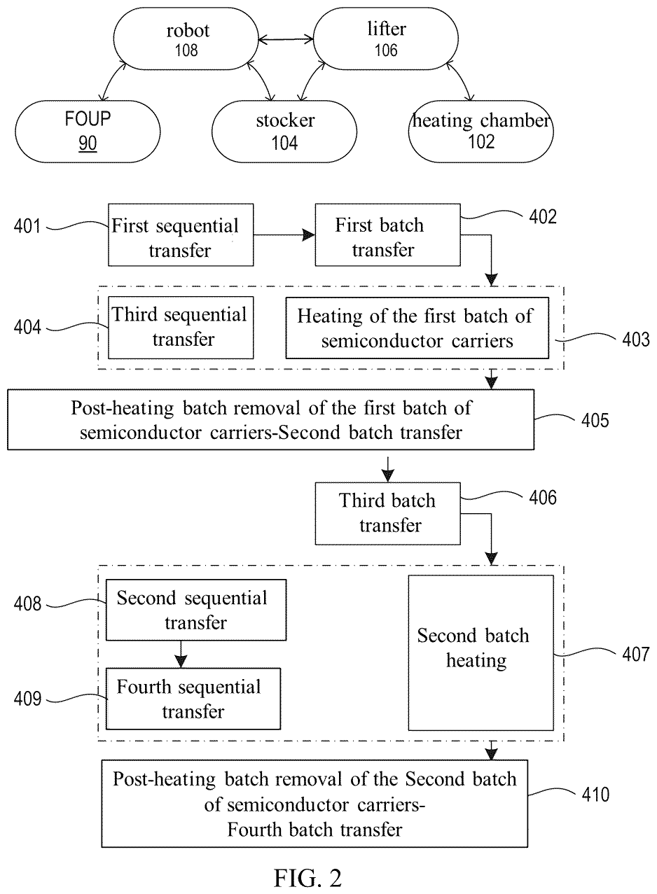

In the embodiments of the present invention shown in FIG. 1A to FIG. 1C, the number of heating chambers 102 is one. In this example, the process of performing a multi-batch heating treatment on semiconductor carriers can refer to the flow chart of FIG. 2 (with the upper part of FIG. 2 listing the actuating structures associated with the procedural steps, which correspond to the steps in the lower part of FIG. 2). As shown, the process includes:
Step 401 (First sequential transfer): The robot sequentially moves the first batch of semiconductor carriers from the FOUP at the load port to the aligner for alignment, then sequentially transfers the first batch of semiconductor carriers to the first metal cassette.
Step 402 (First batch transfer): The lifter batch transfers the first metal cassette to the heating chamber.
Step 403 (Heating of the first batch of semiconductor carriers): The heating chamber heats the first metal cassette to heat the first batch of semiconductor carriers in the first metal cassette.
Step 404 (Third sequential transfer): While step 403 is being performed, the robot sequentially moves the second batch of semiconductor carriers from the FOUP at the load port to the aligner for alignment, then sequentially transfers the second batch of semiconductor carriers to the second metal cassette, followed by the lifter transferring the second metal cassette to the second stocker.
Step 405 (Post-heating batch removal of the first batch of semiconductor carriers-Second batch transfer): After the first batch of semiconductor carriers are heated, the lifter batch removes the first metal cassette from the heating chamber to the first stocker.
Step 406 (Third batch transfer): The lifter batch transfers the second metal cassette to the heating chamber.
Step 407 (Second batch heating): The heating chamber heats the second metal cassette to heat the second batch of semiconductor carriers in the second metal cassette.
Step 408 (Second sequential transfer): While step 407 is being performed, the robot sequentially removes the first batch of semiconductor carriers from the first metal cassette and transfers them, one by one, into the FOUP at the load port.
Step 409 (Fourth sequential transfer): After step 408 is performed, and while step 407 is still in progress, the robot sequentially moves the third batch of semiconductor carriers from the FOUP located at the load port to the aligner for alignment, then sequentially transfers the third batch of semiconductor carriers to the first metal cassette. Subsequently, the lifter transfers the first metal cassette to the first stocker.
Step 410 (Post-heating batch removal of the Second batch of semiconductor carriers—Fourth batch transfer): After the second batch of semiconductor carriers are heated, the lifter removes the second metal cassette from the heating chamber to the second stocker.

The multi-batch heating treatment process shown in FIG. 2 is merely one exemplary operation based on the structure illustrated in FIG. 1A to FIG. 1C. Any adjustment to this exemplary operation that does not increase the duration of the idle state of the heating chamber essentially fall within the scope of feasible variations of the embodiments of the present invention. For example, after the robot is used to sequentially transfer the first batch of semiconductor carriers to the first metal cassette in step 401, and before the lifter is used to transfer the first metal cassette in batches to the heating chamber in step 402, the first metal cassette can be directly batch transferred to the heating chamber by the lifter—for instance, if the first metal cassette continuously remains on the lifter. Alternatively, if the first metal cassette is located in a rack-stacked stocker, the lifter can batch transfer the first metal cassette located in this type of stocker to the heating chamber. In addition, when the metal cassette is transferred to the stocker via the lifter, the lifter can transfer the metal cassette to any available empty stocker, and is not limited to following the numbering (such as first or second, etc.) in the above steps, which is provided only for explanatory assistance. In addition, since in general, the duration of the heating operation performed by the heating chamber on the metal cassette is longer than that of a single sequential transfer operation or a batch transfer operation, it is sufficient for the requisite preceding or succeeding sequential transfer and/or batch transfer of one or several batches of semiconductor carriers to be completed within the timeframe of the duration of the heating operation of the heating chamber on the metal cassette. For example, it is not required that the batch heating of step 407 and the sequential transfer of step 408 be scheduled to start concurrently, nor that the sequential transfer of step 408 and the sequential transfer of step 409 be performed in immediate succession. In some embodiments, the present invention does not require such scheduling restrictions.

The multi-batch heating treatment process shown in FIG. 2 can continue by sequentially transferring the heated second batch of semiconductor carriers back to the FOUP at the load port, while the third batch of semiconductor carriers along with the first metal cassette is transferred to the heating chamber again for heating, and the steps of batch removal of the semiconductor carriers from the heating chamber and sequential unloading from the metal cassette are repeated for each subsequent batch, In this way, multiple batches of semiconductor carriers heating can be continuously completed.

In other words, in some embodiments of the present invention, while a certain batch of semiconductor carriers is being heated within the heating chamber, the robot does not stop working but rather continues to sequentially transfer the next batch of semiconductor carriers to be heated or the previous batch of heated semiconductor carriers. Therefore, when the current batch of semiconductor carriers finishes heating, the next batch of semiconductor carriers to be heated can be immediately batch transferred into the heating chamber for heating treatment, thereby minimizing the idle time of the heating chamber as much as possible. In other words, except for the initial stage of the entire multi-batch heating treatment process, the heating chamber of the equipment for handling semiconductor carriers is maintained in an operation mode rather than an idle mode for nearly the entire workflow. In other embodiments, such as during the execution of the first sequential transfer of step 401 and the first batch transfer of step 402 as shown in FIG. 2, the heating chamber may also be in an operating procedure, such as heating other semiconductor carriers. This means that the steps listed in FIG. 2 of the present invention reflect only a segment of the overall multi-batch heating treatment process window and are not confined to only the initial stage of operation of the equipment for handling semiconductor carriers.

As mentioned above, in some embodiments of the present invention, a part of the lifter can also serve as a stocker. For example, during the first sequential transfer process in step 401, the first metal cassette can be in a state where it can be clamped or supported, so that the robot sequentially transfers the semiconductor carriers to the metal cassette being clamped or supported by the lifter. In some embodiments, the metal cassette can then be directly batch transferred to the heating chamber without passing through the aforementioned n+1 rack-type stockers, or the metal cassette may have originally been located in a special stocker provided by the lifter, making it unnecessary to use the lifter to transfer the first metal cassette to the first stocker during the first sequential transfer process in step 401. Similarly, after the semiconductor carriers are heated, in some embodiments, the semiconductor carriers that are moved out of the heating chamber in batches from the heating chamber by a lifter can be sequentially transferred back to the FOUP at the load port by a robot while the metal cassette being clamped or supported by the lifter.

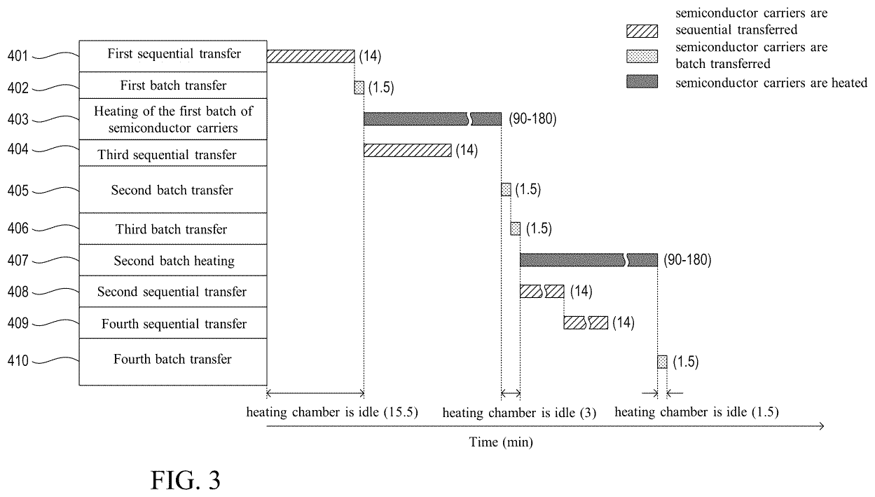

FIG. 3 is a schematic diagram showing the durations of different steps in multi-batch heating treatment processes according to some embodiments of the present invention. As illustrated, in some examples, for the transfer of 50 semiconductor carriers, the process in which the robot sequentially aligns and transfers semiconductor carriers to the metal cassettes, as well as the process of transferring the metal cassettes to the stocker, lasts approximately 14 minutes (i.e., the durations of the first, second, third, and fourth sequential transfers are substantially identical). In contrast, the process of batch-transferring the metal cassettes to the heating chamber, or batch-removing the metal cassettes from the heating chamber, each takes only approximately 1.5 minutes (i.e., the duration of the first, second, third, and fourth batch transfers are substantially identical). The duration of a heating operation program for the semiconductor carrier within the heating chamber may range from approximately 90 minutes to 180 minutes. This duration of the heating operation program includes both the heating-up and cooling-down stages necessary before and after the heating chamber reaches the target process heating temperature. In other words, in some embodiments, the heating operation program can be subdivided into a main operation program, in which semiconductor carrier are baked at set parameter temperatures, and non-main operation programs, such as pre-heating and cooling-down.

Compared to certain comparative embodiments that do not use a stocker and instead rely on a robot to align and sequentially transfer semiconductor carriers directly into a metal cassette fixed within the heating chamber, some embodiments of the present invention include vertically stacked stockers. These stockers are positioned adjacent to the sequential transfer area 302 (see FIG. 1A), thereby reducing the operating distance required for the robot during sequential transfer operations. Therefore, the sequential transfer steps for the same number of semiconductor carriers in comparative embodiments-such as for transferring 50 semiconductor carriers-can be shortened from about 16.67 minutes to about 14 minutes. Additionally, in the comparative embodiment where a stocker is omitted and a robot directly sequentially transfers the heated semiconductor carriers from the heating chamber back to the FOUP at the load port, the duration is approximately 12.5 minutes. In the multi-batch heating treatment process, the comparative embodiment also keeps the heating chamber in an extended idle process during this sequential transfer stage.

As shown in FIG. 3, except for the initial stage of the entire multi-batch heating treatment process (e.g., the first sequential transfer in step 401 and the first batch transfer in step 402 shown in FIG. 2), embodiments of the present invention synchronize the process of sequentially aligning and transferring the semiconductor carriers to the metal cassette by the robot, as well as transferring the metal cassette to the stocker, with the heating operation program of the semiconductor carriers being performed in the heating chamber. That is, the durations of these sequential transfer overlap with the duration of the heating chamber being in an operating state. Therefore, in some embodiments of the present invention, after completing the heating operation program for a previous batch of semiconductor carriers in the heating chamber, the heating chamber does not need to wait for the robot arm to perform preparatory operations such as the sequential transfer of the next batch of semiconductor carriers. Instead, it only takes about 1.5 minutes to batch transfer the heated metal cassettes out of heating chamber, and about 1.5 minutes to batch transfer another metal cassettes loaded with the next batch of semiconductor carriers into the heating chamber, resulting in a total interval of about 3 minutes before beginning the next heating operation program. If the heating chamber has to wait for the robot to sequentially transfer the next batch of semiconductor carriers (for example, when the durations of step 403 and step 404 do not overlap), or if it also has to wait for the robot to sequentially transfer the heated semiconductor carriers back to the FOUP at the load port (for example, when the durations of step 407, step 408, and step 409 do not overlap), the interval time between each heating operation program will be extended to approximately 17 minutes (3 minutes+14 minutes), or even approximately 31 minutes (3 minutes+14 minutes+14 minutes), significantly reducing the batch heating efficiency for the semiconductor carriers.

The duration of the heating operation program for semiconductor carriers in the heating chamber described above is merely illustrative. Different process conditions may require different ranges of heating times. However, in cases where the duration of the required heating operation program in current semiconductor manufacturing is greater than the time required for the robotic arm to sequentially transfer semiconductor carriers between the metal cassette and the FOUP, utilizing the equipment for handling semiconductor carriers as provided by some embodiments of the present invention allows the duration of the semiconductor carrier heating operation time to overlap with the duration for sequential transfer of semiconductor carriers. This substantially benefits the batch heating efficiency for semiconductor carriers. In addition, due to the differences in the transfer mechanisms and actuating components employed for batch transfers and sequential transfers, the durations of the two also differ significantly. In some embodiments, the duration of the first batch transfer may be between one-tenth and one-half of the duration of the first sequential transfer. In other words, the potential delay in the heating operation program mainly stems from the duration of the sequential transfer of semiconductor carriers. Therefore, some embodiments of the present invention focus on overlapping the duration of the sequential transfer of semiconductor carriers with the duration of the heating operation program of the semiconductor carriers.

As previously described, n heating chambers 102 are arranged in a vertically stacked manner on the second side 100B of the processing chamber 100. Accordingly, in other embodiments, as shown in FIG. 4A, FIG. 4B, and FIG. 4C, the number of heating chambers 102 may be two, and the number of stockers 104 may be at least three. In some examples, the first heating chamber 1021 may be vertically stacked above the second heating chamber 1022, and the first stocker 1041 may be vertically stacked above the second stocker 1042 and the third stocker 1043. The lifter 106 is configured to move vertically to transfer metal cassettes among the vertically stacked heating chambers and the vertically stacked stockers. Because the multiple stockers 104 and heating chambers 102 in these embodiments of the present invention are both arranged in stacked configurations (each stacked independently), different stockers 104, different heating chambers 102, or even any stocker 104 and any heating chamber 102 may be located at different horizontal positions. Therefore, it is necessary to use a lifter 106 to move the metal cassette 200 vertically (in the z-axis direction) to different horizontal positions before conducting operational processing. In some embodiments, a work light 103 for indicating the working status of the heating chamber may be set at the top of the uppermost heating chamber (e.g., the first heating chamber 1021 in FIG. 4B) depending on the number of vertically stacked heating chambers, so as to facilitate the observation and monitoring of multiple heating chambers.

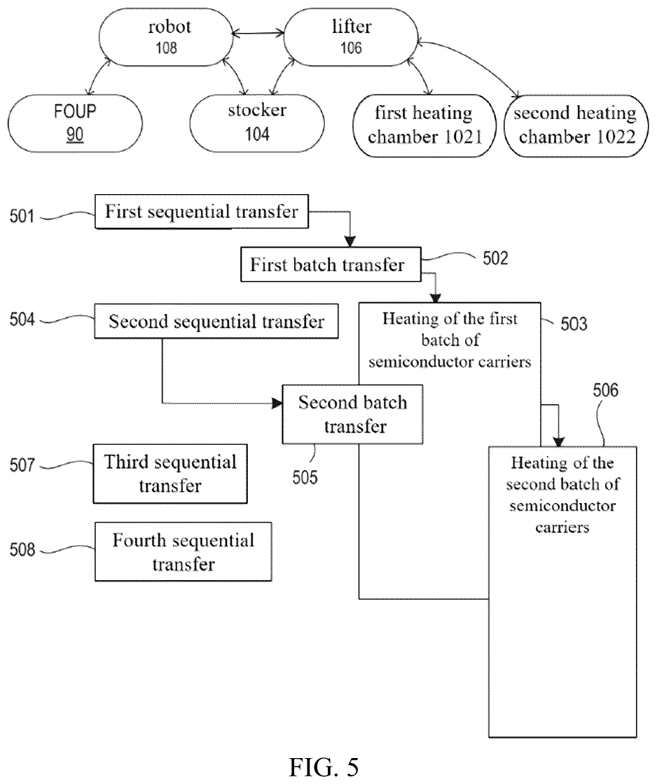

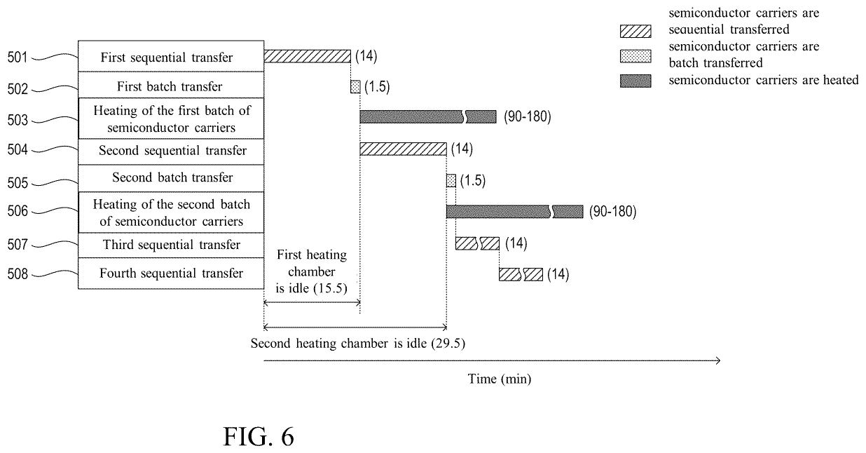

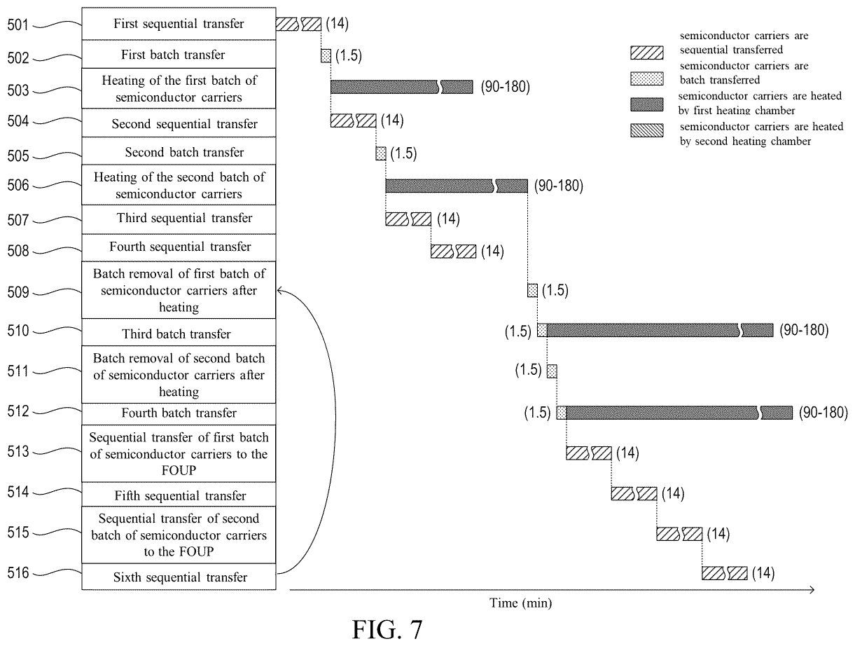

The technical features of the other structures in FIG. 4A, FIG. 4B, and FIG. 4C are as described in the embodiments of FIG. 1A, FIG. 1B, and FIG. 1C, and are not repeated here. In the examples illustrated in FIG. 4A through 4C, the multi-batch heating treatment process for semiconductor carriers can be referenced from the flow charts in FIG. 5 and corresponding timing diagrams of the duration in FIG. 6. As shown, the process may include the initial stages illustrated by steps 501 to 508 (FIG. 5 and FIG. 6) and further include the continuously executed schedule illustrated by steps 509 to 516 (FIG. 7), as disclosed. This exemplary process includes:
Step 501 (First sequential transfer): The robot sequentially moves each of the first batch of semiconductor carriers, initially located in the FOUP at the load port, to the aligner for alignment. After alignment is completed, the robot sequentially transfers the first batch of semiconductor carriers to the first metal cassette, wherein the first metal cassette can be retrieved by the lifter from its original position in one of the stockers or one of the heating chambers.
Step 502 (First batch transfer): The lifter transfers the first metal cassette as a batch to the first heating chamber. The lifter can then retrieve the second metal cassette, which may be originally located in one of the stockers or one of the heating chambers, for example, in the second heating chamber.
Step 503 (Heating of the first batch of semiconductor carriers): The first heating chamber heats the first metal cassette to perform heating on the first batch of semiconductor carriers contained within the first metal cassette.
Step 504 (Second sequential transfer): Following execution of step 501, and concurrently with step 503, the robot sequentially transfers each semiconductor carrier of the second batch, initially located in the FOUP at the load port, to the aligner for alignment. After alignment is completed, the robot sequentially transfers the second batch of semiconductor carriers to the second metal cassette.
Step 505 (Second batch transfer): The lifter transfers the second metal cassette as a batch to the second heating chamber. The lifter can then retrieve the third metal cassette, which may be originally located in one of the stockers, for example, in the first stocker.
Step 506 (Heating of the Second batch of semiconductor carriers): The second heating chamber heats the second metal cassette to perform heating on the second batch of semiconductor carriers contained within the second metal cassette.
Step 507 (Third sequential transfer): After executing step 504, and while steps 503 and 506 are still ongoing, the robotic arm sequentially moves each semiconductor carrier of the third batch, located in the FOUP at the load port, to the aligner for alignment. After alignment is completed, the robot sequentially transfers the third batch of semiconductor carriers to the third metal cassette (On the other hand, the lifter may also move the third metal cassette to one of the stockers, for example, the first stocker, and then retrieve the fourth metal cassette from the second stocker. For brevity, this is not independently listed as a separate step).
Step 508 (Fourth sequential transfer): After execution of step 507, and concurrently with steps 503 and 506, the robot sequentially transfers each semiconductor carrier of the fourth batch, initially located in the FOUP at the load port, to the aligner for alignment. Upon completion of alignment, the robot sequentially transfers the fourth batch of semiconductor carriers to the fourth metal cassette (On the other hand, the lifter may also move the fourth metal cassette to one of the stockers, for example, the second stocker. For brevity, this is not independently listed as a separate step.).
Step 509 (Batch removal of first batch of semiconductor carriers after heating): After heating of the first batch of semiconductor carriers is completed, the lifter batch-removes the first metal cassette from the first heating chamber, for example, to the third stocker.
Step 510 (Third batch transfer): The lifter batch-transfers the third metal cassette from the first stocker to the first heating chamber (after receiving the third batch of semiconductor carriers, the first heating chamber can begin heating them, as shown in FIG. 7).
Step 511 (Batch removal of second batch of semiconductor carriers after heating): After heating of the second batch of semiconductor carriers is completed, the lifter batch-removes the second metal cassette from the second heating chamber, for example, to the first stocker.
Step 512 (Fourth batch transfer): The lifter batch-transfers the fourth metal cassette from the second stocker to the second heating chamber (after receiving the fourth batch of semiconductor carriers, the second heating chamber can begin heating them, as shown in FIG. 7).
Step 513 (Sequential Transfer of first batch of semiconductor carriers to the FOUP): The lifter retrieves the first metal cassette from the third stocker, and the robot sequentially transfers the first batch of semiconductor carriers from the first metal cassette to the FOUP at the load port.
Step 514 (Fifth Sequential Transfer): The robotic arm sequentially transfers each semiconductor carrier of the fifth batch, initially located in the FOUP at the load port, to the aligner for alignment. After alignment is completed, the robot sequentially transfers the fifth batch of semiconductor carriers to the first metal cassette. After the sequential transfer is completed, the first metal cassette can be further transferred to the first stocker by the lifter.
Step 515 (Sequential Transfer of second batch of semiconductor carriers to the FOUP): The lifter retrieves the second metal cassette from the second stocker, and the robot sequentially transfers the second batch of semiconductor carriers contained therein to the FOUP at the load port.
Step 516 (Sixth Sequential Transfer): The robot sequentially moves each semiconductor carrier of the sixth batch, located in the FOUP at the load port, to the aligner for alignment. After the alignment is completed, the robot sequentially transfers the sixth batch of semiconductor carriers to the second metal cassette. After sequential transfer is completed, the second metal cassette can be further transferred to the second stocker by the lifter.

After step 516 is completed, the process returns to the state following step 508, meaning that the first and second heating chambers are undergoing heating, and the semiconductor carriers for subsequent heating are ready and waiting in the stockers for batch transfer into the heating chambers. Therefore, similar to steps 509 and 511, the heated semiconductor carriers are batch-removed, and the next batch of semiconductor carriers to be heated is batch-transferred to the heating chamber in step 510 and step 512. Then, in steps 513 through 516, the robot is allowed to continue operating while the first and second heating chambers are performing their operation programs, to sequentially transfer the semiconductor carriers, and the lifter can also batch transfer the metal cassettes into the stocker. These steps allow the idle metal cassettes to be loaded with semiconductor carriers and placed into a standby state. Steps 509 to 516 can be considered as one cycle, which is repeated following completion of step 516. In this cycle, the semiconductor carriers that have undergone heat treatment can be transported out in real time to free the metal cassettes for the robot to perform the next loading operation. In this example, the first and second heating chambers have a total of two spaces, the first, second, and third stockers have a total of three spaces, and the lifter's fork also provides one space. Among these six spaces, four metal cassettes can be rotated and moved.

The aforementioned initial stage (i.e., steps 501 to 508) may refer to a portion of the multi-batch heating treatment process as disclosed in the present invention, and is not limited to the very beginning of operation for the equipment for handling semiconductor carriers. Therefore, portions of the process not described in these steps may involve the heating chamber performing other operating programs. In addition, in different embodiments of the present invention (for example, with one heating chamber as in FIG. 2 and two heating chambers as in FIG. 5), references to “first sequential/batch transfer steps”, “the second sequential/batch transfer steps”, etc. serve to distinguish different process steps between embodiments. Identical step names across different embodiments do not necessarily indicate technical content.

For example, in a scenario involving transferring 50 semiconductor carriers, in a comparative embodiment with two side-by-side heating chambers, no stockers, and thus direct alignment and then sequential transfer of semiconductor carriers by a robot to metal cassettes fixed in the heating chambers, the initial stage may take up to 33.34 minutes (16.67 minutes+16.67 minutes) before the second heating chamber can start the heating operations. By contrast, in some embodiments of the present invention, the second heating chamber 1022 can begin heating operations approximately 31 minutes (14 minutes+14 minutes+1.5 minutes+1.5 minutes) after batch transfer of semiconductor carriers begins.

Furthermore, as illustrated in the continuously executed schedule example shown in FIG. 7, the idle processes of the first and second heating chambers are considerably shortened. This is because, when a heating chamber is performing the heating operation for a batch of semiconductor carriers, the sequential transfer of the next batch of semiconductor carriers has already been completed and is awaiting batch transfer into the heating chamber. In other words, in the continuously executed schedule, the operating period of the heating chambers is minimally, or even not at all, affected by the duration of sequential transfer of semiconductor carriers by the robot.

For example, in certain embodiments of the invention, the scheduling permits the robot to continuously and sequentially transfer subsequent batches of semiconductor carriers from the FOUP at the load port to empty metal cassettes in a stocker while the first and second heating chambers are performing their operation programs. In addition, during the operation time of the first heating chamber and the second heating chamber, the robot has sufficient time to sequentially remove(unload) the heated semiconductor carriers from the metal cassette to the FOUP at the load port, so that they can be directed to subsequent semiconductor process stations. In some embodiments of the present invention, when there are two or more heating chambers, the operational interval for any heating chamber can be shortened to only the time for two batch transfers of metal cassettes (for example, 1.5 minutes+1.5 minutes), without being affected by the longer duration of the sequential transfer of semiconductor carriers. Moreover, with two or more heating chambers, when one heating chamber is waiting for a metal cassette to be batch-transferred in or out, the other heating chamber(s) can continue performing operation programs. Therefore, the present invention substantially minimizes the likelihood that all heating chambers are in an idle process simultaneously, thereby greatly improving the batch heating efficiency of semiconductor carriers.

Additionally, in most cases, when the robot sequentially transfers semiconductor carriers, the metal cassette for receiving these semiconductor carriers is located on the lifter to allow the robot to have a better sequential transfer angle. Therefore, the duration of sequential transfer usually does not overlap with the duration of batch transfer. However, in other cases, through different designs of temporary storage spaces or further improvements to the metal cassette structure, the stacked stocker can also provide a suitable sequential transfer angle, making it possible for the duration of sequential transfer to overlap with that of batch transfer. The present invention is not limited to any one of them.

As shown in the aforementioned FIG. 1A to FIG. 1C and FIG. 4A to FIG. 4C, in some embodiments of the present invention, the equipment 10 for handling semiconductor carriers may include a central control unit 114. The central control unit 114 may comprise a processor and associated storage device, operably coupled to the processor for automated control of the component structures of the equipment 10 for handling semiconductor carriers, including automatic execution of the processes and/or the corresponding time schedule as illustrated in FIG. 2, FIG. 3, FIG. 5, FIG. 6, and FIG. 7. For example, the processor may be configured, such as by executing programming non-transiently stored on the storage device, so that to control the lifter to move vertically to the height of the second stocker to batch-retrieve multiple semiconductor carriers; and controls the lifter to move vertically to the height of the heating chamber to batch-place the multiple semiconductor carriers into the heating chamber, thereby completing the process of batch-transferring multiple semiconductor carriers from the metal cassette in the stocker to the heating chamber. In some embodiments, the processor may be configured, for example, by executing programming non-transiently stored on the storage device, to optimize process scheduling such that the duration of the first sequential transfer, the duration of the second sequential transfer, the duration of the third sequential transfer, and the duration of the fourth sequential transfer each maximally overlap with the operating time of the heating chamber. This scheduling strategy mitigates the impact of relatively time-consuming sequential transfer steps on overall heating chamber uptime. Maximizing the time overlap of the duration(s) means that the durations of the first, second, third, and fourth sequential transfers are directed to fall, as much as possible, 100% within the operating time of the heating chamber. In other words, sequential transfer of semiconductor carriers should, as far as possible, not be performed when the heating chamber is in an idle process. As previously described, the duration of the heating chamber's heating operation for the metal cassette is longer than that of a single sequential transfer operation. Therefore, performing sequential transfer of semiconductor carriers within the operating period of the heating chamber provides a more accommodating time window for such transfer. As a result, there is greater flexibility in the operational parameters for sequential transfer, allowing the work intensity of the robot to be suitably set, rather than having to compress the duration of a single sequential transfer operation in some comparative embodiments to reduce the duration of the heating chamber's idle process, which may lead to the robot being set to excessive work intensity, increasing the probability of errors or shortening its service life.

In some examples, when transferring 50 semiconductor carriers, the combined duration for sequential alignment and transfer of the carriers to the metal cassette by the robot, followed by metal cassette transfer to the stocker, is approximately 14 minutes. In contrast, the duration for batch-transferring the metal cassette into the heating chamber or batch-removing the metal cassette from the heating chamber is only about 1.5 minutes each. The duration of the heating operation program for the semiconductor carriers in the heating chamber ranges from approximately 90 to 180 minutes, including both the heating-up and cooling-down stages required before and after the heating chamber reaches the target heating temperature. Compared to some comparative embodiments that do not use a stocker and directly utilize a robot to sequentially transfer semiconductor carriers, after alignment, to a metal cassette fixed in heating chamber, some embodiments of the present invention include vertically stacked stockers. Because these stockers are spatially arranged adjacent to the sequential transfer area 302 (see FIG. 1A), the operating distance for the robot to carry out sequential transfer is reduced. Therefore, for the same number of semiconductor carriers (ex. 50 semiconductor carriers), the sequential transfer step can be shortened from about 16.67 minutes in the comparative embodiment to about 14 minutes. Furthermore, in the comparative embodiment lacking stockers, where the robot sequentially transfer the heated semiconductor carriers directly from the heating chamber back to the FOUP at the load port, the duration of this process is about 12.5 minutes. In a multi-batch heating treatment process, such comparative embodiments also place the heating chamber in a lengthy idle process during this sequential transfer phase.

The foregoing summarizes the structures of several embodiments so that those skilled in the art may better understand the aspects of the present disclosure. Those skilled in the art will realize that they may readily use this disclosure as a basis for designing or modifying other manufacturing processes and structures for carrying out the same purposes and/or achieving the same advantages of the embodiments described herein. Those skilled in the art will also recognize that such equivalent constructions do not depart from the spirit and scope of the present disclosure, and that various changes, substitutions, and modifications may be made herein without departing from the spirit and scope of the present disclosure.

1. An equipment for handling semiconductor carriers, comprising:
a processing chamber;
n heating chambers communicated with the processing chamber;
at least n+1 stockers disposed within the processing chamber;
a lifter disposed within the processing chamber and configured to transfer a high-temperature-resistant, transferable metal cassette to one of the n heating chambers or one of the at least n+1 stockers, the transferable metal cassette being configured to accommodate and batch-transfer a plurality of semiconductor carriers; the at least n heating chambers and the at least n+1 stockers being configured to accommodate the transferable metal cassette;
a robot disposed within the processing chamber and configured to sequentially transfer the plurality of semiconductor carriers to the transferable metal cassette via a carrier loading system; and
wherein n is an integer greater than or equal to 1.

2. The equipment according to claim 1, wherein each of the at least n heating chambers includes a magnetic mechanism to fix the transferable metal cassette.

3. The equipment according to claim 1, wherein the lifter is placed between the at least n heating chambers and the at least n+1 stockers, and is configured to transfer the transferable metal cassette back and forth between one of the at least n heating chambers and one of the at least n+1 stockers.

4. The equipment according to claim 3, wherein n is equal to 2, and
the first heating chamber is vertically stacked on the second heating chamber;
the first stocker is vertically stacked on the second stocker and the third stocker; and
the lifter is configured to move in a vertical direction.

5. The equipment according to claim 1, further comprises an aligner communicating with the processing chamber.

6. The equipment according to claim 1, wherein the processing chamber comprises:
a batch transfer zone adjacent to the at least n heating chambers, wherein only batch transfer operations are performed in the batch transfer zone; and
a sequential transfer zone adjacent to the carrier loading system, wherein only sequential transfer operations are performed in the sequential transfer zone.

7. The equipment according to claim 6, further comprises:
a lifter track located in the batch transfer zone, which is configured to guide displacement of the lifter in a single direction.

8. The equipment according to claim 1, wherein the transferable metal cassette is disposed on a fork of the lifter when the robot sequentially transfers the plurality of semiconductor carriers to the transferable metal cassette.

9. An equipment for handling semiconductor carriers, comprising:
a processor configured to cause:
a robot positioned in a processing chamber to perform a first sequential transfer, in which a plurality of semiconductor carriers are sequentially transferred from a carrier loading system to a first transferable metal cassette; and
the transferable metal cassette positioned in the processing chamber to be transferred to a stocker or a heating chamber.

10. The equipment according to claim 9, wherein the transferable metal cassette positioned in the processing chamber to be transferred to a stocker or a heating chamber comprises:
a lifter performing a first batch transfer, in which the first transferable metal cassette is transferred from a first stocker to the heating chamber for batch transferring the plurality of semiconductor carriers.

11. The equipment according to claim 10, wherein a duration of the first batch transfer is between one-tenth and one-half of a duration of the first sequential transfer.

12. The equipment according to claim 10, wherein the processor is further configured to cause:
the robot to perform a second sequential transfer, in which, while the heating chamber is in an operation process, the plurality of semiconductor carriers are sequentially transferred from the transferable metal cassette to the carrier loading system.

13. The equipment according to claim 10, wherein the first sequential transfer and the first batch transfer are performed while the heating chamber is in an idle process.

14. The equipment according to claim 12, wherein the processor is further configured to cause:
the robot to perform a third sequential transfer, in which, while the heating chamber is in the operation process, the plurality of semiconductor carriers are sequentially transferred from one of the plurality of carrier loading system to a second transferable metal cassette.

15. The equipment according to claim 14, wherein the processor is further configured to cause:
the robot to perform a fourth sequential transfer, in which, while the heating chamber is in the operation process, the plurality of semiconductor carriers are sequentially transferred from one of the plurality of carrier loading system to the first transferable metal cassette.

16. The equipment according to claim 15, wherein a duration of the second sequential transfer, a duration of the third sequential transfer, and a duration of the fourth sequential transfer are substantially the same as the duration of the first sequential transfer.

17. The equipment according to claim 16, wherein the processor is further configured to cause:
the lifter to perform:
a second batch transfer, in which, while the heating chamber is in an idle process, the plurality of semiconductor carriers are batch transferred from the heating chamber to the first stocker;
a third batch transfer, in which, while the heating chamber is in an idle process, the plurality of semiconductor carrier are batch transferred from the second stocker to the heating chamber; and
a fourth batch transfer, in which, while the heating chamber is in an idle process, the plurality of semiconductor carriers are batch transferred from the heating chamber to the second stocker;
wherein a duration of the second batch transfer, a duration of the third batch transfer, and a duration of the fourth batch transfer are substantially the same as the duration of the first batch transfer.

18. The equipment according to claim 17, wherein the processor is further configured to:
during the third batch transfer, control the lifter to move vertically to a level of the second stocker so as to batch-acquire the plurality of semiconductor carriers; and
during the third batch transfer, control the lifter to move vertically to a level of the heating chamber so as to batch-place the plurality of semiconductor carriers into the heating chamber.

19. The equipment according to claim 10, wherein the processor is further configured to maximize, respectively, an overlap of the duration of the first sequential transfer, the duration of the second sequential transfer, the duration of the third sequential transfer, and the duration of the fourth sequential transfer with a duration during which the heating chamber is in an operating state.

20. The equipment according to claim 10, further comprising a storage device coupled to the processor.
